(19) United States
(12) Patent Application Publication
(10) Pub. No.: US 2009/0127648 A1
(43) Pub. Date: May 21, 2009

(54) Hybrid Gap-fill Approach for STI Formation

(76) Inventors: Neng-Kuo Chen, Sinshih (TW); Chih-Hsiang Chang, Taipei (TW); Cheng-Yuan Tsai, Chu-Pei (TW); Wei-Chung Wang, Taipei (TW); Chun-Te Li, Renwu (TW)

Correspondence Address: SLATER & MATSIL, L.L.P., 17950 PRESTON ROAD, SUITE 1000, DALLAS, TX, 75252, US

(21) Appl. No.: 11/969,168

(22) Filed: Jan. 3, 2008

Related U.S. Application Data
(60) Provisional application No. 60/988,294, filed on Nov. 15, 2007.

(51) Int. Cl. H01L 23/58; H01L 21/762

(52) U.S. Cl. 257/506; 438/425; 257/E21.545; 257/E23.002

(57) ABSTRACT

A method of forming a shallow trench isolation region is provided. The method includes providing a semiconductor substrate comprising a top surface; forming an opening extending from the top surface into the semiconductor substrate; performing a first deposition step to fill a first dielectric material into the opening using a first deposition method. The first deposition method has a bottom deposition rate substantially greater than a sidewall deposition rate. The method further includes isotropically etching the first dielectric material, wherein at least a bottom portion of the first dielectric material remains after the etching; and performing a second deposition step to fill a remaining portion of the opening with a second dielectric material. The first deposition method may be a high-density plasma chemical vapor deposition. The second deposition method may be a high-aspect ratio process.

This application claims the benefit of the following commonly assigned U.S. provisional patent application: Application Ser. No. 60/988,294, filed Nov. 15, 2007, entitled “Hybrid Gap-fill Approach for STI Formation,” which patent application is incorporated herein by reference.

### TECHNICAL FIELD

This invention relates generally to integrated circuits, and more particularly to structures and manufacturing methods of shallow trench isolation (STI) regions.

### BACKGROUND

Modem integrated circuits are formed on the surfaces of semiconductor substrates, which are mostly silicon substrates. Semiconductor devices are isolated from each other by isolation structures formed on the surface of the respective semiconductor substrates. The isolation structures include field oxides and shallow trench isolation (STI) regions.

Field oxides are often formed using local oxidation of silicon (LOCOS). A typical formation process includes blanket forming a mask layer on a silicon substrate, and then patterning the mask layer to expose certain areas of the underlying silicon substrate. A thermal oxidation is then performed in an oxygen-containing environment to oxidize the exposed portions of the silicon substrate. The mask layer is then removed.

With the down-scaling of integrated circuits, STI regions are increasingly used as the isolation structures. FIGS. 1 and 2 illustrate intermediate stages in the formation of an STI region. First, an opening is formed in substrate 10, for example, using etching. The opening has an aspect ratio, which equals to the ratio of depth D1 to width W1. The aspect ratio becomes increasingly greater when the integrated circuits are increasingly scaled down. For 40 nm technology and below, the aspect ratio will be greater, and sometimes far greater, than 7.0. Oxide 12, preferably a silicon oxide, is filled into the opening, until the top surface of oxide 12 is higher than the top surface of silicon substrate 10.

The increase in the aspect ratio causes problems. Referring to FIG. 1, in the filling of the opening, the high aspect ratio will adversely result in the formation of void 14, which is a result of the pre-mature sealing in the top region of the filling oxide 12. After a chemical mechanical polish (CMP) to remove excess oxide 12, STI region 16 is left in the opening, as is shown in FIG. 2. It is likely that void 14 is exposed after the CMP. In subsequent process steps, conductive materials such as polysilicon may be filled into the opening, causing the bridging, and even the shorting of integrated circuits in some circumstances.

Conventionally, oxide 12 is often formed using one of the two methods, high-density plasma chemical vapor deposition (HDP) and high aspect-ratio process (HARP). The HDP may fill gaps with aspect ratios less than about 6.0 without causing voids. The HARP may fill gaps with aspect ratios less than about 7.0 without causing voids. However, as the aspect ratios are close to 7.0, even if no voids are formed, the central portions of STI regions 16 formed using HARP are often weak. The weak portions may be damaged by the CMP processes, which in turn cause voids after the CMP. When the aspect ratios further increase to greater than 7.0, voids start to appear even if the HARP is used. Accordingly, the existing gap-filling techniques can only fill gaps having aspect ratios less than 7.0 without causing voids.

U.S. Pat. No. 7,033,945 teaches a method including the steps of forming a STI opening, partially filling the STI opening with BSG, performing a reflow to re-shape the BSG, performing a dip in HF acid, and then performing a second filling step to fully fill the STI opening. However, such process incurs extra cost of reflowing the BSG, and may also reduce the throughput. New gap-filling methods are thus needed.

### SUMMARY OF THE INVENTION

In accordance with one aspect of the present invention, a method of forming a shallow trench isolation region is provided. The method includes providing a semiconductor substrate comprising a top surface; forming an opening extending from the top surface into the semiconductor substrate; performing a first deposition step to fill a first dielectric material into the opening using a first deposition method. The first deposition method has a bottom deposition rate substantially greater than a sidewall deposition rate. The method further includes isotropically etching the first dielectric material, wherein at least a bottom portion of the first dielectric material remains after the etching; and performing a second deposition step to fill a remaining portion of the opening with a second dielectric material. The first deposition method may be a high-density plasma chemical vapor deposition. The second deposition method may be a high-aspect ratio process.

In accordance with another aspect of the present invention, a method of forming an integrated circuit structure includes providing a semiconductor substrate comprising a top surface; forming an opening extending from the top surface into the semiconductor substrate; forming a liner oxide in the opening; performing a first deposition step to fill a first dielectric material into the opening using a bottom-up deposition method; isotropically etching at least a portion of a sidewall portion of the first dielectric material; performing a second deposition step to fill a remaining portion of the opening with a second dielectric material using a conformal deposition method; and performing a planarization to remove an excess portion of the second dielectric material.

In accordance with yet another aspect of the present invention, a method of forming an integrated circuit structure includes providing a semiconductor substrate comprising a first top surface; forming an opening extending from the first top surface into the semiconductor substrate; forming a liner oxide in the opening; performing a high-density plasma chemical vapor deposition (HDP) to fill a first dielectric material into the opening, wherein a bottom portion of the first dielectric material has a second top surface lower than the first top surface; performing a wet dip to substantially remove a sidewall portion of the first dielectric material; and performing a high aspect ratio process (HARP) to fill a remaining portion of the opening with a second dielectric material.

In accordance with yet another aspect of the present invention, an integrated circuit structure includes a semiconductor substrate comprising a top surface; an opening extending from the top surface into the semiconductor substrate; a liner oxide lining the opening; a first oxide filling a bottom portion of the opening, wherein the first oxide has a first etching rate; and a second oxide filling a top portion of the opening, wherein the second oxide has a second etching rate different than the first etching rate.

In accordance with yet another aspect of the present invention, an integrated circuit structure includes a semiconductor substrate comprising a first top surface; an opening extending from the first top surface into the semiconductor substrate; a liner oxide lining the opening; a first oxide filling a bottom portion of the opening, wherein the first oxide has a first density; and a second oxide filling a top portion of the opening, wherein the second oxide has a second density different than the first density.

Advantageously, by using the embodiments of the present invention, shallow trench isolation regions having great aspect ratios, for example, greater than about 7.0 or even greater, may be formed without incurring voids.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 and 2 illustrate cross-sectional views in a conventional shallow trench isolation (STI) formation process; and

FIGS. 3 through 10 are cross-sectional views of intermediate stages in the manufacturing of a STI embodiment.

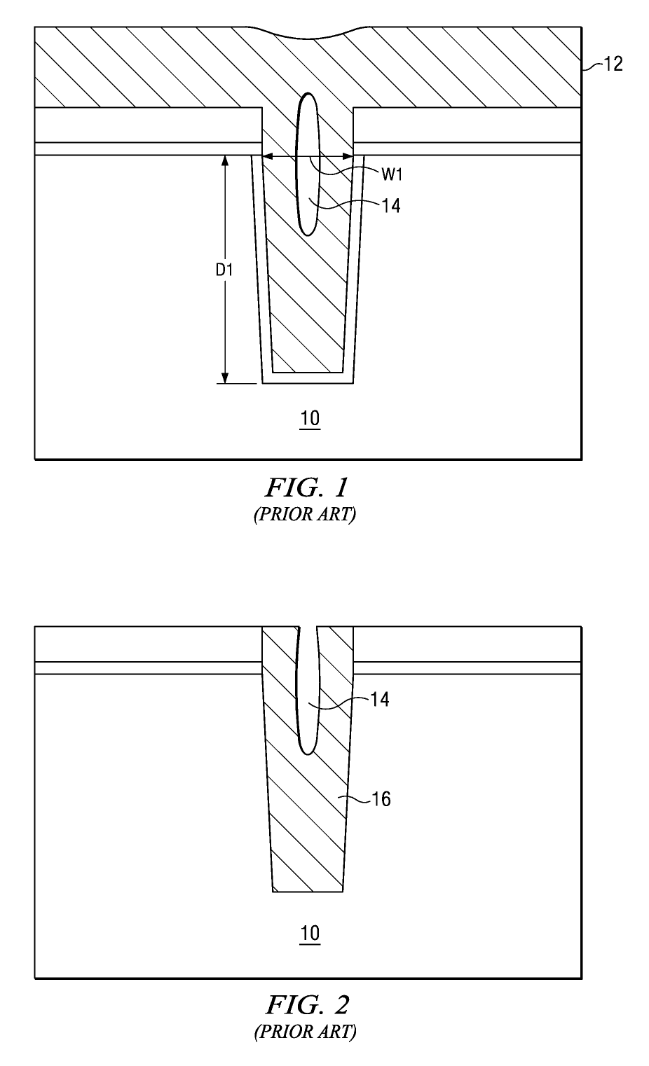

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming a shallow trench isolation (STI) region is provided. The intermediate stages in the manufacturing of a preferred embodiment of the present invention are illustrated. The variations of the preferred embodiment are then discussed. Throughout the various views and illustrative embodiments of the present invention, like reference numbers are used to designate like elements.

Referring to FIG. 3, semiconductor substrate 20 is provided. In the preferred embodiment, semiconductor substrate 20 includes silicon. Other commonly used materials, such as carbon, germanium, gallium, arsenic, nitrogen, indium, and/or phosphorus, and the like, may also be included in semiconductor substrate 20. Semiconductor substrate 20 may be formed of single-crystalline or compound materials, and may be a bulk substrate or a semiconductor-on-insulator (SOI) substrate.

Pad layer 22 and mask layer 24 are formed on semiconductor substrate 20. Pad layer 22 is preferably a thin film comprising silicon oxide formed, for example, using a thermal oxidation process. Pad layer 22 may act as an adhesion layer between semiconductor substrate 20 and mask layer 24. Pad layer 22 may also act as an etch stop layer for etching mask layer 24. In the preferred embodiment, mask layer 24 is formed of silicon nitride, for example, using low-pressure chemical vapor deposition (LPCVD). In other embodiments, mask layer 24 is formed by thermal nitridation of silicon, plasma enhanced chemical vapor deposition (PECVD), or plasma anodic nitridation. Mask layer 24 is used as a hard mask during subsequent photolithography process. Photoresist 26 is formed on mask layer 24 and is then patterned, forming opening 28 in photoresist 26.

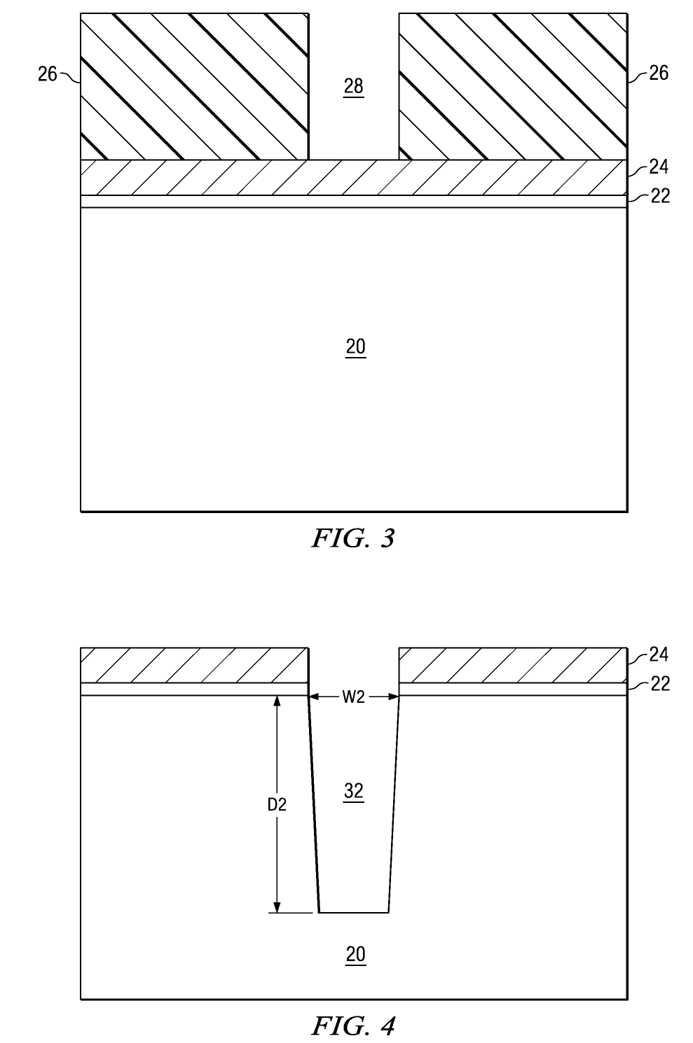

Referring to FIG. 4, mask layer 24 and pad layer 22 are etched through opening 28, exposing underlying semiconductor substrate 20. The exposed semiconductor substrate 20 is then etched, forming trench 32. Photoresist 26 is then removed. Next, a cleaning is preferably performed to remove a native oxide of semiconductor substrate 20. The cleaning may be performed using diluted HF. In an exemplary embodiment, the depth D2 of trench 32 is between about 2100 Å and about 2500 Å, while the width W2 is between about 420 Å and about 480 Å. One skilled in the art will realize, however, that the dimensions recited throughout the descriptions are merely examples, and may be changed to suit different scales of integrated circuits.

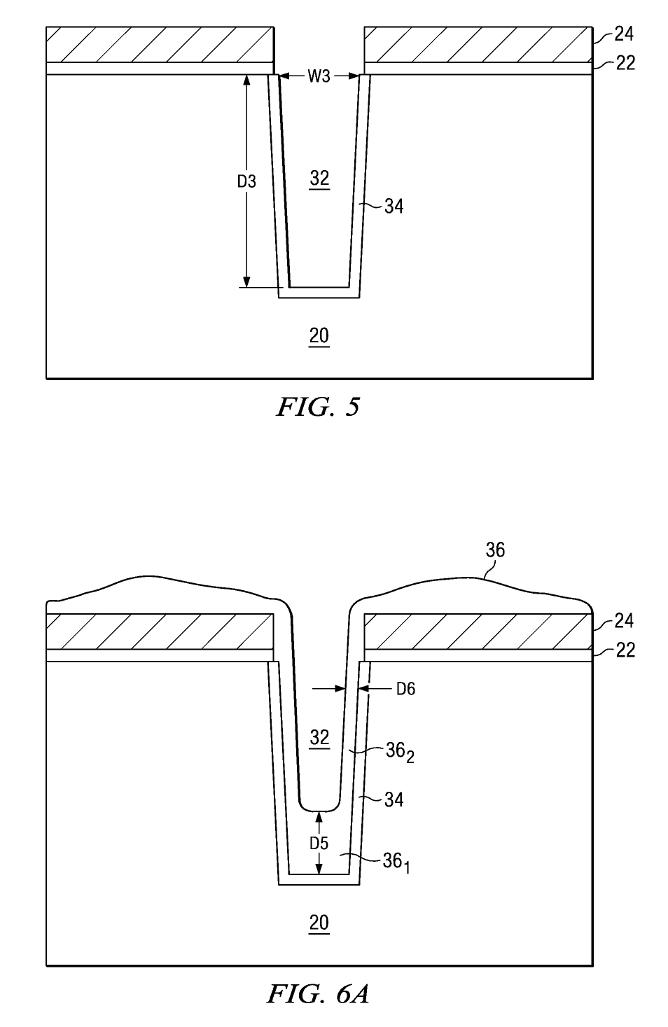

Liner oxide 34 is then formed in opening 32, as is shown in FIG. 5. In an embodiment, liner oxide 34 may be a thermal oxide having a preferred thickness of between about 20 Å to about 500 Å. In other embodiments, liner oxide 34 is formed using in-situ steam generation (ISSG). Alternatively, liner oxide 34 may be formed using a deposition technique that can form conformal oxide layers, such as selective area chemical vapor deposition (SACVD), high aspect ratio process (HARP), and the like. The formation of liner oxide 34 rounds the corners of opening 32, which reduces the electrical fields, and hence improves the performance of the resulting integrated circuit.

After the formation of liner oxide 34, the remaining portion of opening 32 has a width W3, which is measured at the same level as a top surface of substrate 20, and a depth D3. The ratio of depth D3 to width W3 is referred to the aspect ratio of opening 32. In an exemplary embodiment, the aspect ratio of opening 32 is greater than about 7.0. In other exemplary embodiments, the aspect ratios may even be greater than about 8.5, although they may also be lower than about 7.0.

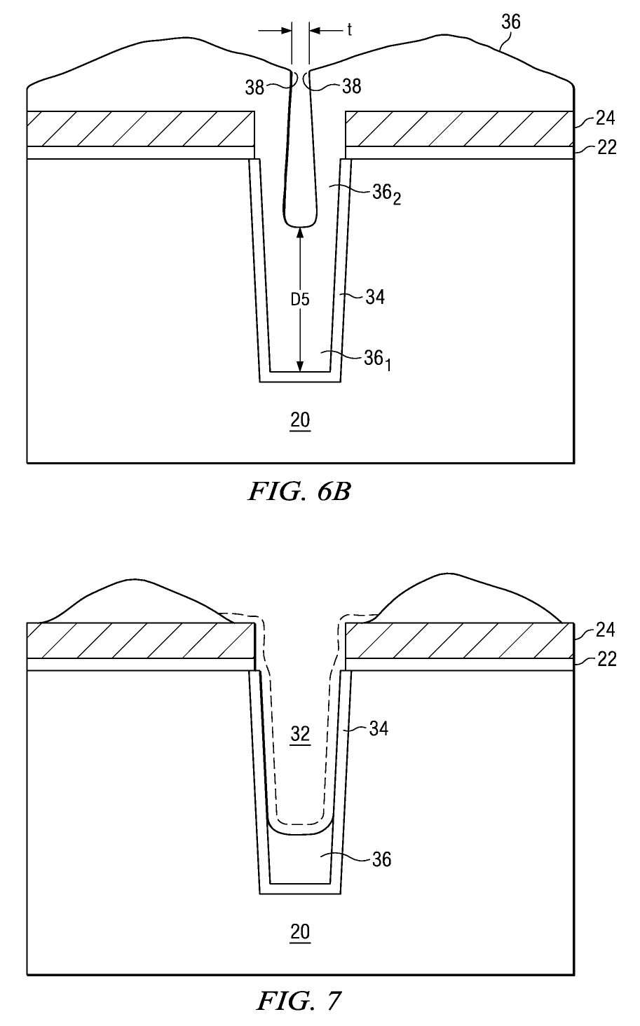

Referring to FIG. 6A, trench 32 is partially filled with dielectric material 36. Preferably, dielectric material 36 includes silicon oxide, and hence is referred to as oxide 36, although other dielectric materials, such as SiN, SiC, or the like, may also be used. In the preferred embodiment, the filling of oxide 36 is performed using a bottom-up deposition technique, which results in a highly non-conformal layer. As a result of the bottom-up deposition technique, the bottom thickness D5 of the bottom portion 36₁ of oxide 36 is significantly greater than the sidewall thickness D6 of the sidewall portions 36₂, with a ratio of D5/D6 being greater than about 5, and more preferably greater than about 10. In an exemplary embodiment, oxide 36 is formed using high-density plasma chemical vapor deposition (HDP). The HDP generates high-density plasma. With a bias voltage applied, the HDP deposition is highly directional, which is downward in this case. As a result, the resulting D5/D6 ratio may be as high as about 9, or even higher. In an exemplary embodiment, oxide 36 has a bottom thickness D5 of about 500 Å and about 1400 Å. Correspondingly, the sidewall thickness D6 may be only about 50 Å to about 150 Å, for example.

Next, oxide 36 is partially etched by an isotropic etching step, and a resulting structure is shown in FIG. 7. In the preferred embodiment, the isotropic etching includes a wet dip, for example, in diluted hydrofluoric (HF) acid solution. In other embodiments, dry etch can be used with no bias voltage applied, so that the resulting etching is not directional. In the isotropic etching, the sidewall portions 36₂ is at least reduced (as shown by the dashed lines), and preferably substantially removed. Since the etching is isotropic, the bottom portion 36₁ is etched by a substantially same thickness as the sidewall portions 36₂. Since oxide 36 may be formed of silicon oxide, which may be the same material as in liner oxide 34, care may be taken to ensure that liner oxide 34 is not etched through.

Preferably, the isotropic etching brings the aspect ratio of the remaining opening 32 to lower than about 7.0, and even more preferably, less than about 6.0, so that remaining opening 32 may be filled without the incurring of void. In an exemplary embodiment, the etched portion of oxide 36 has a thickness of between about 60 Å and about 120 Å. The preferable amount of the etched portion of oxide 36 is related to the original aspect ratio of opening 32 as shown in FIG. 5, and the higher the original aspect ratio is, the more oxide 36 needs to be etched. In other words, the greater amount the oxide 36 is removed, the greater the original aspect ratio can be without causing void.

The bottom thickness D5 has an upper limit and a lower limit. FIG. 6B illustrates a scenario for determining the upper limit of thickness D5. It is to be realized that no matter how great the bottom thickness D5 is, the top ends of oxide 36 should not be sealed before the isotropic etching is performed. In FIG. 6B, the tips 38 of the top portions of oxide 36 are about to, but do not, touch each other. In this case, the distance t between tips 38 may be as small as about 2 Å. The bottom thickness D5 as shown in FIG. 6B is hence the upper limit. If the bottom thickness D5 is to further increase, and tips 38 touch each other to seal a void in, the subsequent isotropic etching will have very limited, if any at all, effect to the reduction in aspect ratio.

The lower limit of the bottom thickness D5 (refer to FIG. 6A) may be determined as follows: after the isotropic etching of oxide 36, the aspect ratio of the remaining opening 32 as shown in FIG. 7 needs to be lower than the highest aspect ratio (for example, 7.0) that can be handled by the subsequent gap-filling process without causing a void. Accordingly, the bottom thickness D5 is such that after the isotropic etching, the aspect ratio of the remaining opening 32 is just (maybe barely) below the highest aspect ratio.

If, however, after the cycle of the bottom-up deposition and the isotropic etching of oxide 36, the aspect ratio of the remaining opening 32 is still not low enough for forming a void-free STI region, additional cycles, each including a bottom-up deposition and an isotropic etching may be added, with each of the additional cycles having the effect of further lowering the aspect ratio.

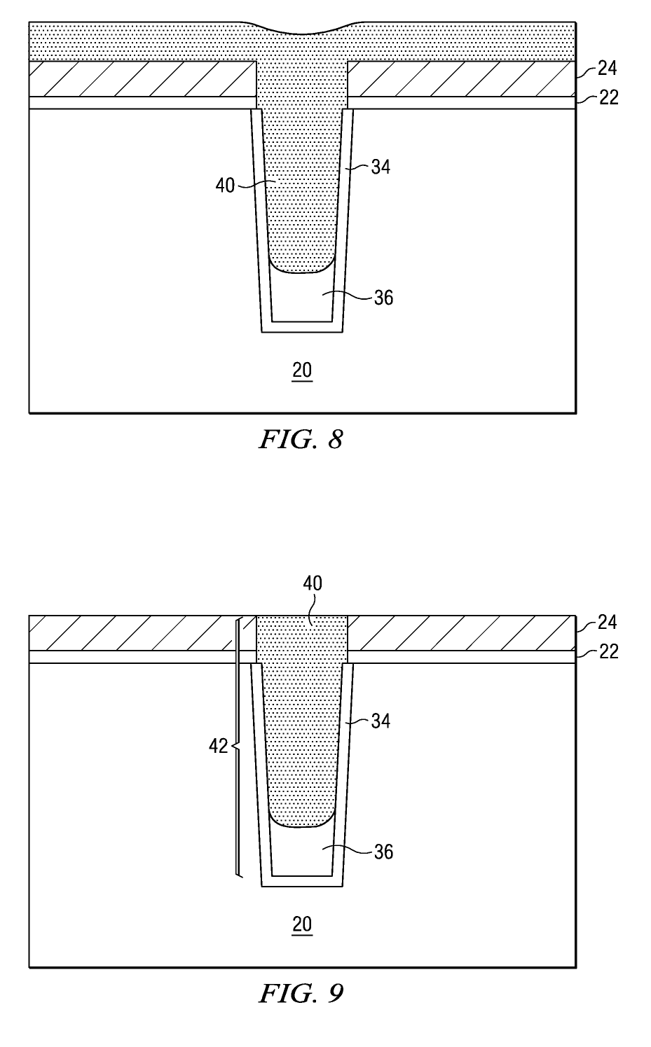

Referring to FIG. 8, the remaining portion of opening 32 is filled by dielectric 40, until the top surface of oxide 40 is higher than the top surface of mask layer 24. Dielectric 40 is referred to as oxide 40 hereinafter, even though it may be formed of other materials other than oxides, such as SiON, SiN, or the like. The filling of opening 32 is preferably performed using a method less prone to voids. In the preferred embodiment, oxide 40 is formed using high aspect ratio process (HARP), which uses ozone (O₃) and tetraethyl orthosilicate (TEOS) as process gases. As a result, oxide 40 includes the TEOS oxide, which is also silicon oxide. HARP has the ability to form highly conformal films, and hence the remaining opening 32 may be filled with no voids formed. Alternatively, other conformal deposition methods, such as SACVD or atmospheric pressure chemical vapor deposition (APCVD), may be used, wherein TEOS and oxygen may be used as the process gases. Dielectrics 36 and 40 may be formed of same or different materials.

Alternatively, oxide 40 may be formed using other methods, including methods having bottom-up capabilities, as long as there is no void formed in oxide 40. For example, HDP may be used to form oxide 40 if the aspect ratio of the remaining opening 32 is less than 6.0. However, the HDP has an adverse re-sputtering effect, and hence care needs to be taken to ensure that mask layer 24 is not damaged.

A chemical mechanical polish (CMP) is then performed to remove excess dielectric material 40, forming a structure as shown in FIG. 9. Mask layer 24 may act as a CMP stop layer. The remaining portions of dielectric material 36 and 40 form STI region 42.

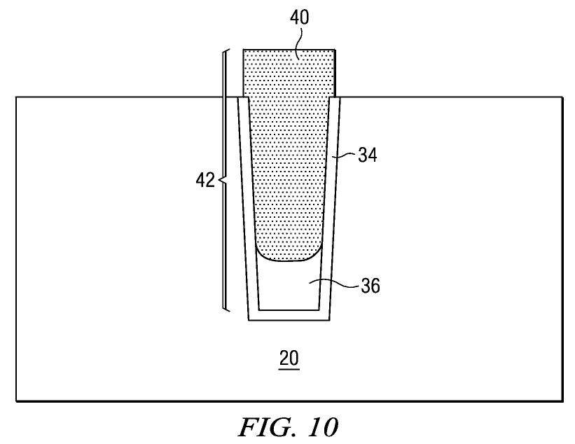

Mask layer 24 and pad layer 22 are then removed, as shown in FIG. 10. Mask layer 24, if formed of silicon nitride, may be removed by a wet clean process using hot H₃PO₄, while pad layer 22 may be removed using diluted HF if formed of silicon oxide. As is known in the art, the removal of mask layer 24 and pad layer 22 and the corresponding cleaning processes will cause the top surface of STI region 42 to be lowered.

In the resulting structure as shown in FIG. 10, STI region 42 includes two types of dielectric materials, oxide 36 and oxide 40. Oxide 36 and oxide 40 may be formed of different dielectric materials. Even if they are formed of substantially same materials with the same compositions, for example, silicon oxides (or TEOS oxides), due to the difference in the formation processes, they may have distinguishable characteristics. For example, oxide 36 formed of HDP has a higher density than that of oxide 40 formed of HARP, and both densities are smaller than the densities of the thermal oxide. The characteristic differences are also reflected by the difference in etching rates. If the etching rate of thermal silicon oxide is used as criteria, then the relative etching rate of oxide 36 as compared to the etching rate of thermal silicon oxide is about 1.1, while the relative etching rate of oxide 40 as compared to the etching rate of thermal silicon oxide is about 1.25.

The embodiments of the present invention have several advantageous features. By separating the gap-filling process into two deposition steps or more, and adding an isotropic etching step therebetween, STI regions having high aspect ratios can be formed without voids. In experiments, STI regions with aspect ratios of between 7.4 and 8.0 have been made, and even higher aspect ratios are expected to be attainable. The embodiments of the present invention thus enable the formation of STI regions for 40 nm and below, which demands STI regions to have high aspect ratios.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an integrated circuit structure, the method comprising:
providing a semiconductor substrate comprising a top surface;
forming an opening extending from the top surface into the semiconductor substrate;
performing a first deposition step to fill a first dielectric material into the opening using a first deposition method, wherein the first deposition method has a bottom deposition rate substantially greater than a sidewall deposition rate;
isotropically etching the first dielectric material, wherein at least a bottom portion of the first dielectric material remains after the etching; and
performing a second deposition step to fill a remaining portion of the opening with a second dielectric material.

2. The method of claim 1, wherein the second deposition step is performed using a second deposition method different from the first deposition method.

3. The method of claim 1, wherein the first deposition method is high-density plasma chemical vapor deposition (HDP).

4. The method of claim 1, wherein the second deposition method is conformal.

5. The method of claim 4, wherein the second deposition method is a high aspect ratio process (HARP).

6. The method of claim 1, wherein the isotropic etching comprises a method selected from the group consisting essentially of wet dipping and unbiased dry etching.

7. The method of claim 1, wherein before the first deposition step, the opening has an aspect ratio of greater than about 7.0, and after the isotropic etching, a remaining portion of the opening has an aspect ratio of less than about 6.0.

8. The method of claim 1, wherein before the isotropic etching, tips of sidewall portions of the first dielectric material have a distance of greater than about 2 Å.

9. The method of claim 1, wherein the first and the second dielectric materials are silicon oxides.

10. A method of forming an integrated circuit structure, the method comprising:
providing a semiconductor substrate comprising a top surface;
forming an opening extending from the top surface into the semiconductor substrate;
forming a liner oxide in the opening;
performing a first deposition step to fill a first dielectric material into the opening using a bottom-up deposition method;
isotropically etching at least a portion of a sidewall portion of the first dielectric material;
performing a second deposition step to fill a remaining portion of the opening with a second dielectric material using a conformal deposition method; and
performing a planarization to remove an excess portion of the second dielectric material.

11. The method of claim 10, wherein the first deposition method comprises a bottom-up chemical vapor deposition (CVD) process, and wherein the second deposition method comprises a conformal CVD process.

12. The method of claim 11, wherein the first deposition method comprises a high-density plasma chemical vapor deposition (HDP).

13. The method of claim 11, wherein the second deposition method comprises a high aspect ratio process (HARP).

14. The method of claim 10, wherein the step of isotropically etching removes only a portion of a sidewall portion of the first dielectric material.

15. The method of claim 10, wherein the isotropic etching substantially fully removes the sidewall portion of the first dielectric material.

16. The method of claim 10, wherein the sidewall portion removed by the isotropic etching has a thickness of between about 60 Å and about 120 Å.

17. The method of claim 10, wherein before the isotropic etching, a remaining portion of the opening has an aspect ratio of greater than about 7.0, and wherein after the isotropic etching, the remaining portion of the opening has an aspect ratio of less than about 6.0.

18. A method of forming an integrated circuit structure, the method comprising:
providing a semiconductor substrate comprising a first top surface;
forming an opening extending from the first top surface into the semiconductor substrate;
forming a liner oxide in the opening;
performing a high-density plasma chemical vapor deposition (HDP) to fill a first dielectric material into the opening, wherein a bottom portion of the first dielectric material has a second top surface lower than the first top surface;
performing a wet dip to substantially remove a sidewall portion of the first dielectric material; and
performing a high aspect ratio process (HARP) to fill a remaining portion of the opening with a second dielectric material.

19. The method of claim 18, wherein the first and the second dielectric materials each comprises silicon oxide.

20. The method of claim 18, wherein before the wet dip, a remaining portion of the opening has an aspect ratio of greater than about 7.0, and wherein after the wet dip, the remaining portion of the opening has an aspect ratio of less than about 6.0.

21. An integrated circuit structure comprising:
a semiconductor substrate comprising a top surface;
an opening extending from the top surface into the semiconductor substrate;
a liner oxide lining the opening;
a first oxide filling a bottom portion of the opening, wherein the first oxide has a first etching rate; and
a second oxide filling a top portion of the opening, wherein the second oxide has a second etching rate different than the first etching rate.

22. The integrated circuit structure of claim 21, wherein an inner region defined by the liner oxide has a first aspect ratio of greater than about 7.0, and wherein the second oxide has a second aspect ratio of less than about 6.0.

23. The integrated circuit structure of claim 21, wherein the first and the second oxides are silicon oxides.

24. The integrated circuit structure of claim 23, wherein the first and the second etching rates are greater than an etching rate of a thermal oxide.

25. The integrated circuit structure of claim 23, wherein the first etching rate is smaller than the second etching rate.

26. The integrated circuit structure of claim 23, wherein the first etching rate and the second etching rate have a ratio of about 1.1/1.25.

27. The integrated circuit structure of claim 21 further comprising an extension portion on the bottom portion and encircling the top portion, the extension portion having a same etching rate as the bottom portion.

28. An integrated circuit structure comprising:
a semiconductor substrate comprising a first top surface;
an opening extending from the first top surface into the semiconductor substrate;
a liner oxide lining the opening;
a first oxide filling a bottom portion of the opening, wherein the first oxide has a first density; and
a second oxide filling a top portion of the opening, wherein the second oxide has a second density different than the first density.

29. The integrated circuit structure of claim 28, wherein an inner region defined by the liner oxide has a first aspect ratio of greater than about 7.0, and wherein the second oxide has a second aspect ratio of less than about 6.0.

30. The integrated circuit structure of claim 28, wherein the first and the second densities are less than a density of a thermal oxide.

31. The integrated circuit structure of claim 28, wherein the first density is greater than the second density.

32. The integrated circuit structure of claim 28 further comprising an extension portion on the bottom portion and encircling the top portion, the extension portion having a same density as the bottom portion.
